(19) United States
(12) Patent Application Publication
(10) Pub. No.: US 2015/0230337 A1
(43) Pub. Date: Aug. 13, 2015

(54) DISPLAY DEVICE AND METHOD OF MANUFACTURING THE SAME

(71) Applicant: SAMSUNG DISPLAY CO., LTD., Yongin-City (KR)

(72) Inventors: DONG-IN KIM, Suwon-si (KR); Hyun-Seok Hong, Asan-si (KR); Sang-Min Jeon, Uiwang-si (KR); Joo-Yeon Won, Seoul (KR); Chong-Guk Lee, Seoul (KR)

(21) Appl. No.: 14/527,229

(22) Filed: Oct. 29, 2014

(30) Foreign Application Priority Data
Feb. 13, 2014 (KR) 10-2014-0016506

(51) Int. Cl. H05K 1/11; H05K 3/36; H05K 1/18

(52) U.S. Cl. CPC H05K 1/118; H05K 1/181; H05K 1/189; H05K 1/111; H05K 3/361; H05K 2201/10128

(57) ABSTRACT

A display device includes a display panel including a display area and a non-display area, a plurality of driver integrated circuits mounted on the non-display area of the display panel by a COG method, a printed circuit board (PCB) configured to provide a signal to the plurality of driver integrated circuits, and a flexible printed circuit (FPC) configured to transfer the signal from the PCB to the plurality of driver integrated circuits. The FPC has a first end portion and a second end portion opposite to the first end portion. The first end portion is attached on the non-display area of the display panel by a FOG method, and the second end portion is attached on the PCB. A width of the second end portion is different from a width of the first end portion.

### CROSS REFERENCE TO RELATED APPLICATION

This application claims priority from Korean Patent Applications No. 10-2014-0016506, filed on Feb. 13, 2014, the disclosure of which is hereby incorporated by reference herein in its entirety.

### TECHNICAL FIELD

Example embodiments of the inventive concept relate to electronic devices. More particularly, example embodiments of the inventive concept relate to display devices including a flexible printed circuit, and methods of manufacturing the same.

### DISCUSSION OF RELATED ART

In a display device, a driver integrated circuit may be mounted on a display panel by a chip-on-glass (COG) method, and a flexible printed circuit (FPC) may be mounted on the display panel by a film-on-glass (FOG) method. Compared with conventional mounting method, the COG and FOG methods are relatively simple and may increase the relative size of a display area in the display panel so that, the COG and FOG methods are widely used in the display device manufacturing process.

Meanwhile, a plurality of interconnection lines electrically connect a driver integrated circuit to the FPC. When driver integrated circuits respectively connect to FPCs through the interconnection lines, it may be necessary that the number of the FPC be the same as the number of the driver integrated circuits.

On the other hand, when a plurality of driver integrated circuits connect to one FPC through the interconnection lines, a length of each of the interconnection lines may become longer and each of spaces between the interconnection lines may become smaller. Thus, resistance of the interconnection lines may increase.

Signal levels such as data signals, power supply voltages provided to pixel units may be fluctuated by high resistance of the interconnection lines, so that some noise may be generated in a display area of the display device. For example, a defect on the display such as horizontal lines on display area may occur.

### SUMMARY

Example embodiments provide a display device having a plurality of interconnection lines arranged at a display panel, the interconnection lines having small resistance.

Example embodiments provide a method of manufacturing the display device.

According to example embodiments, a display device may include a display panel including a display area and a non-display area, a plurality of driver integrated circuits mounted on the non-display area of the display panel by a chip-on-glass (COG) method, a printed circuit board (PCB) configured to provide a signal to the plurality of driver integrated circuits, and a flexible printed circuit (FPC) having a first end portion and a second end portion opposite to the first end portion configured to transfer the signal from the PCB to the plurality of driver integrated circuits. The first end portion may be attached on the non-display area of the display panel by a film-on-glass (FOG) method, and the second end portion may be attached on the PCB. A width of the second end portion may be different from a width of the first end portion.

In example embodiments, the width of the first end portion may be greater than the width of the second end portion.

In example embodiments, the FPC may have a trapezoid shape where the width of the first end portion is greater than the width of the second end portion.

In example embodiments, the display device may further include a plurality of interconnection lines disposed on the non-display area of the display panel, the plurality of interconnection lines electrically connecting the plurality of driver integrated circuits to the FPC.

In example embodiments, the plurality of driver integrated circuits may include a first driver integrated circuit and a second driver integrated circuit that is adjacent to the first driver integrated circuit. The plurality of interconnection lines may include a plurality of first interconnection lines connecting the first driver integrated circuit to the FPC and a plurality of second interconnection lines connecting the second driver integrated circuit to the FPC. A length of each of the first interconnection lines may be substantially the same as a length of each of the second interconnection lines.

In example embodiments, each of spaces between the first interconnection lines may be greater than each of spaces of FPC internal lines that are disposed at the second end portion of the FPC.

In example embodiments, the interconnection lines may include a transparent conductive material.

In example embodiments, the interconnection lines may include copper or aluminum.

In example embodiments, the PCB may be a flexible printed circuit board (FPCB).

In example embodiments, the signal provided to the driver integrated circuits may include a data signal and a power supply voltage.

In example embodiments, the FPC may be electrically connected to the display panel through an anisotropic conductive film (ACF).

In example embodiments, the FPC may be electrically connected to the PCB through an ACF.

According to example embodiments, a method of manufacturing a display device may include mounting a plurality of driver integrated circuits on a non-display area of a display panel by a chip-on-glass (COG) method, attaching a first end portion of a flexible printed circuit (FPC) on the display panel by a film-on-glass (FOG) method, in which the first end portion has a first width, attaching a second end portion of the FPC opposite to the first end portion on a printed circuit board (PCB) that is configured to provide a signal to the plurality of driver integrated circuits. The second end portion may have a second width that is different from the first width.

In example embodiments, the first width may be greater than the second width.

In example embodiments, the method of manufacturing the display device may further include forming a plurality of interconnection lines on the non-display area of the display panel, and the plurality of interconnection lines electrically connect the plurality of driver integrated circuits to the FPC.

In example embodiments, the plurality of driver integrated circuits may include a first driver integrated circuit and a second driver integrated circuit that is adjacent to the first driver integrated circuit. The plurality of interconnection lines may include a plurality of first interconnection lines connecting the first driver integrated circuit chip to the FPC and a plurality of second interconnection lines connecting the second driver integrated circuit to the FPC. A length of each of the first interconnection lines is substantially the same as a length of each of the second interconnection lines.

In example embodiments, each of spaces between the first interconnection lines may be greater than each of spaces of FPC internal lines that are disposed at the second end portion of the FPC.

In example embodiments, the FPC may be electrically connected to the display panel through an anisotropic conductive film (ACF).

In example embodiments, the FPC may be electrically connected to the PCB through an ACF.

In accordance with an example embodiment, a display device is provided. The display device includes a display panel including a display area and a non-display area, and a pixel unit disposed in the display area of the display panel. The non-display area of the display panel includes a non-display area base substrate, a first insulation layer disposed on the non-display area base substrate, a first driver integrated circuit bonding pad and a second driver integrated circuit bonding pad disposed on the first insulation layer, an interconnection line disposed on the first insulation layer, a second insulation layer including a contact hole disposed on the first insulation layer, a flexible printed circuit (FPC) bonding pad disposed on the first insulation layer and connected to the interconnection line, a driver integrated circuit disposed on the second insulation layer and including an input bump and an output bump which are respectively connected to the first driver integrated circuit bonding pad and the second driver integrated circuit bonding pad, respectively via an anisotropic conductive film (ACF), and in which the driver integrated circuit is coupled to the pixel unit, and a flexible printed circuit (FPC) configured to transfer the signal from the PCB to the driver integrated circuit. The FPC includes a first end portion and a second end portion opposite to the first end portion. The first end portion is electrically and physically connected to the FPC bonding pad via an anisotropic conductive film (AFC), and a width of the first end portion is greater than a width of the second end portion.

In addition, the non-display area of the display panel of the display device further includes a printed circuit board (PCB) configured to provide a signal to the driver integrated circuit. The PCB includes a PCB bonding pad which is electrically and physically connected to the second end portion of the FPC via an anisotropic conductive film (AFC), a PCB line pattern configured to transfer a data signal and a power supply voltage to the FPC, and a cover layer configured to protect the PCB line pattern from damage.

Therefore, the display device according to example embodiments may include a FPC in which the width of the first end portion is greater than the width of the second end portion, so that one FPC may be connected to the plurality of driver integrated circuits. Thus, the lengths of the interconnection lines may decrease significantly compared with conventional interconnection lines. Also, each of spaces between the interconnection lines may be greater than the conventional interconnection lines. As a result, the resistance of the interconnection lines may decrease, so that a defect on the display (e.g., horizontal lines on display area) caused by unintended impulses and external noises may be minimized or prevented.

In addition, the method of manufacturing the display device according to example embodiments may include attaching the FPC having the first end portion and the second end portion to the display panel and the PCB, and with the width of the first end portion being greater than the width of the second end portion. Thus, the resistance of the interconnection lines may decrease, so that a defect on the display (e.g., horizontal lines on display area) caused by unintended impulses and external noises may be minimized or decreased. Also, the interconnection lines may be relatively simply arranged, so that reliability of the display device may be increased.

### BRIEF DESCRIPTION OF THE DRAWINGS

Example embodiments can be understood in more detail from the following description taken in conjunction with the accompanying drawings, in which:

FIG. 1 is a plane view of a display device according to an example embodiment.

FIG. 2 is an enlarged view illustrating an example of a portion ‘A’ of FIG. 1.

FIG. 3 is a cross-sectional view taken along the line I-I′ of FIG. 1.

FIG. 4 is an enlarged view illustrating an example of a portion ‘B’ of FIG. 3.

FIG. 5 is an enlarged view illustrating an example of a portion ‘C’ of FIG. 3.

FIG. 6 is a plane view of a display device according to an example embodiment.

FIG. 7 is a plane view of a display device according to an example embodiment.

FIG. 8 is a plane view of a display device according to an example embodiment.

FIG. 9 is a flow chart of a method of manufacturing a display device according to an example embodiment.

### DETAILED DESCRIPTION OF EXAMPLE EMBODIMENTS

Example embodiments will be described more fully hereinafter with reference to the accompanying drawings, in which various embodiments are shown.

In the drawings, the thickness of layers, films, panels, regions, etc. may be exaggerated for clarity. Like reference numerals designate like elements throughout the specification. It will be understood that when an element such as a layer, film, region, or substrate is referred to as being “on” another element, it can be directly on the other element or intervening elements may also be present.

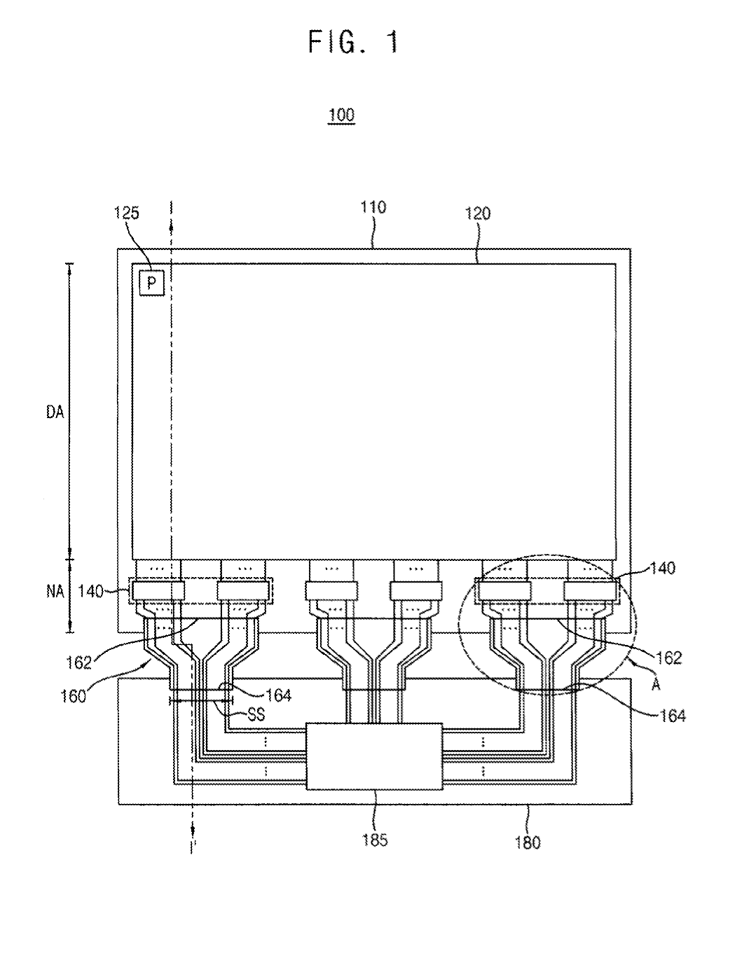

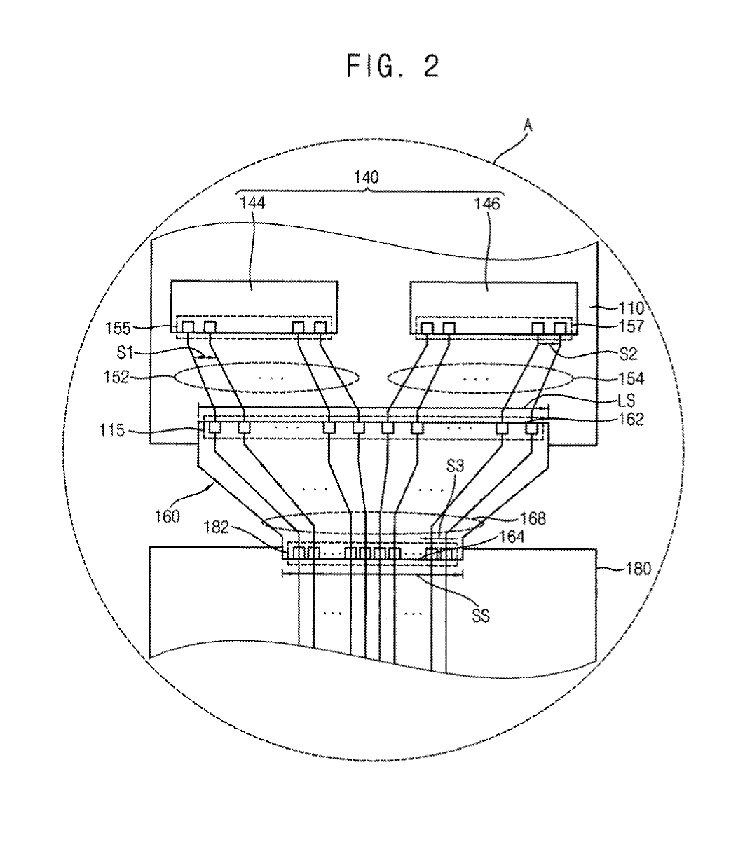

As used herein, the singular forms, “a”, “an”, and “the” are intended to include plural forms as well, unless the context clearly indicates otherwise. FIG. 1 is a plane view of a display device according to an example embodiment, and FIG. 2 is an enlarged view illustrating an example of a portion ‘A’ of FIG. 1.

Referring to FIGS. 1 and 2, the display device 100 may include, for example, a display panel 110, a plurality of driver integrated circuits 140, a flexible printed circuit (FPC) 160, a printed circuit board (PCB) 180, and a plurality of interconnection lines 152 and 154.

According to example embodiments, the display device 100 may be any display device, such as, for example, a LCD (liquid crystal display) device, an OLED (organic light emitting display) device, a PDP (plasma display panel) display device, etc.

As illustrated in FIG. 1, the display panel 110 may include a display area DA where a pixel unit 120 is formed and a non-display area NA on which a plurality of driver integrated circuits 140 and a portion of FPC 160 are mounted. The pixel unit 120 may be formed in, for example, a matrix form having a plurality of rows and a plurality of columns. The pixel unit 120 may include a plurality of pixels 125.

The driver integrated circuits 140 may be mounted on the non-display area NA of the display panel 110 using, for example, a chip-on-glass (COG) method. For example, the driver integrated circuits 140 may be mounted on a glass substrate of the display panel 110 by disposing an anisotropic conductive film (ACF) between the driver integrated circuits 140 and the glass substrate and by pressing at high temperature. According to example embodiments, the driver integrated circuits 140 may be, for example, a data driver integrated circuit applying a data voltage to the display area DA of the display panel 110, a scan driver integrated circuit applying a gate voltage to the display area DA of the display panel 110, or an integrated driver integrated circuit where the data driver and the scan driver are integrated. Although FIG. 1 illustrates an example of the display device 100 where six driver integrated circuits 140 are mounted on the display panel 110, the number of driver integrated circuits is not limited thereto.

The plurality of driver integrated circuits 140 may include, for example, an input bump unit for receiving a signal from an external device (e.g., the PCB 180) through the FPC 160, and an output bump unit for transferring a signal to the pixel unit 120 of the display panel 110. In an example embodiment, as illustrated in FIG. 2, a first driver integrated circuit 144 and a second driver integrated circuit 146 may respectively include, for example, the input bump units 155 and 157 for receiving a signal from the PCB 180 through the FPC 160, and output bumps unit for transferring a signal to the pixel unit 120 of the display panel 110. The second driver integrated circuit 146 may be adjacent to the first driver integrated circuit 144.

The input bumps 155 and 157 may include, for example, a plurality of input bumps arranged in a predetermined form (e.g., in a straight line). In an example embodiment, each of input bumps 155 and 157 may be formed with a conductive material, such as, for example, gold (Au), copper (Cu), nickel (Ni), etc., but example embodiments are not limited thereto. The plurality of input bumps 155 and 157 may be respectively coupled to an input pad unit formed on the glass substrate of the display panel 110 using, for example, the COG method. The input pad unit may include a plurality of input pads. The plurality of input pads may be respectively coupled to the interconnection lines (e.g., first and second interconnection lines 152 and 154). Thus, the first and second driver integrated circuits 144 and 146 may receive, for example, a power supply voltage, a ground voltage, a data signal, etc. through the plurality of input pads and the plurality of input bumps 155 and 157. In example embodiments, the plurality of input bumps may be, for example, directly contacted to first interconnection lines 152 and second interconnection lines 154 but example embodiments are not limited thereto.

The first and second driver integrated circuits 144 and 146 may be configured to transfer the data signal, the gate signal, etc. to the pixel unit 120 of the display panel 110 through the output bump unit.

The first and second driver integrated circuits 144 and 146 may include, for example, an internal ground line. While the display device 100 operates, the internal ground line may receive the ground voltage (e.g., a system ground voltage) through at least one ground input bump among the plurality of input bumps 155 and 157, and may provide the ground voltage to the first and second driver integrated circuits 144 and 146.

The PCB 180 may be configured to provide a signal to the plurality of driver integrated circuits 140. In an example embodiment, the signal may include, for example, the power supply voltage, and the data signal. The data signal may be provided to the first and second driver integrated circuits 144 and 146 to control the operation of the display device 100. For example, the data signal may include image data and control data to control the operation of the display device 100 while the display device 100 operates. In an example embodiment, the PCB 180 may include, for example, a timing controller 185 generating the signals and a power supply generating the power supply voltages.

In an example embodiment, the FPC 160 may be electrically connected to the PCB 180 through the ACF. As illustrated in FIG. 2, the PCB 180 may include, for example, a PCB bonding pad unit 182 where the FPC 160 is attached. In other words, the FPC 160 may be attached to the PCB bonding pad unit 182 by the ACF. The PCB bonding pad unit 182 may be formed with a conductive material, and may be coupled to an internal circuit of the FPC 160. Thus, the PCB bonding pad unit 182 may combine the PCB 180 with the FPC 160, and may transfer the signal from the PCB 180 to the FPC 160. A width of the PCB bonding pad unit 182 may correspond to, for example, a width SS of a second end portion 164 of the FPC 160. When a plurality of FPCs are mounted on the display device 100, the number of PCB bonding pad unit may be the same as the number of the plurality of FPCs.

A first end portion 162 of the FPC 160 may be attached on an edge of the non-display area NA of the display panel 110 using a film-on-glass (FOG) method. The second end portion 164 of the FPC 160 may be attached on the PCB 180. The width of the second end portion 164 (i.e., indicated SS) may be different from a width of the first end portion 162 (i.e., indicated LS). In an example embodiment, the display panel 110 may be electrically connected to the FPC 160 through the ACF, and the PCB 180 may be electrically connected to the FPC 160 through the ACF. Thus, the FPC 160 may transfer the signal from the PCB 180 to the display panel 110 and the first and second driver integrated circuits 144 and 146. The ACF may include, for example, a conductive particle for electrical connection and an adhesive resin for physical connection. FPC internal lines 168 may be connected to the interconnection lines (i.e., the first and second interconnection lines 152 and 154) through the FPC bonding pad unit 115, and may be connected to the internal circuits of the PCB 180 through the PCB bonding pad unit 182.

In an example embodiment, the width LS of the first end portion 162 may be greater than the width SS of the second end portion 164. Therefore, one FPC 160 may be connected to the first and second interconnection lines 152 and 154 that transfer the signal to the plurality of driver integrated circuits (e.g., the first and second driver integrated circuits 144 and 146). Further, the width SS of the second end portion 164 does not increase, so that a width of the PCB bonding pad unit 182 and the number of the PCB bonding pad units may be not increase. In an example embodiment, the FPC 160 may have, for example, a trapezoid shape where the width LS of the first end portion 162 is greater than the width SS of the second end portion 164.

The first and second interconnection lines 152 and 154 may be arranged at the non-display area NA of the display panel 110. The plurality of driver integrated circuits 140 may be connected to the FPC 160 through the first and second interconnection lines 152 and 154. In an example embodiment, as illustrated in FIG. 2, the first and second interconnection lines 152 and 154 may be arranged at the display device to electrically connect the first and second driver integrated circuits 144 and 146 to the FPC 160, respectively. For example, the first interconnection lines 152 may be connected to the input bump unit of the first driver integrated circuit 144 (or the input pad unit of the display panel 110) and the FPC bonding pad unit 115 of the display panel 110. Thus, the signals generated in the PCB 180 may be transferred to the first driver integrated circuit 144. Similarly, the signals generated in the PCB 180 may be transferred to the second driver integrated circuit 146 through the second interconnection lines 154.

In an example embodiment, the first and second interconnection lines 152 and 154 may be formed with a transparent conductive material such, for example, as indium tin oxide (ITO), Indium zinc oxide (IZO), aluminum doped zinc oxide (AZO), zinc oxide (ZnOx), tin oxide (SnOx), etc. Alternatively, in an example embodiment, the first and second interconnection lines 152 and 154 may be formed with a low-resistance metal such as, for example, copper, aluminum, chromium, tantalum, molybdenum, tungsten, neodymium, silver, or alloys thereof, etc. In an example embodiment, the first and second interconnection lines 152 and 154 may have, for example, a multi layer structure where a plurality of conductive layers is stacked. As these are examples, the material included in the first and second interconnection lines 152 and 154 are not limited thereto.

In an example embodiment, a length of each of the first interconnection lines 152 may be substantially the same as a length of each of the second interconnection lines 154. The first interconnection lines 152 may connect the FPC 160 to the first driver integrated circuit 144 and the second interconnection lines 154 may connect the FPC 160 to the second driver integrated circuit 146. The second driver integrated circuit 146 may be adjacent to the first driver integrated circuit 144. Alternatively, in an example embodiment, the lengths of the first and second interconnection lines 152 and 154 may correspond to the shortest distance between the first and second driver integrated circuits 144 and 146 and the FPC 160, respectively. Thus, the first and second interconnection lines 152 and 154 may be straight lines. As a result, the lengths of the first and second interconnection lines 152 and 154 may decrease significantly compared with conventional interconnection lines. Therefore, the resistance of the first and second interconnection lines 152 and 154 may decrease.

However, these are examples. The number of driver integrated circuits connected to one FPC is not limited thereto. For example, three or four driver integrated circuits may be connected to one FPC through the interconnection lines.

In an example embodiment, each of spaces between the first interconnection lines 152 (i.e., indicated S1) and each of spaces between the second interconnection lines 154 (i.e., indicated S2) may be greater than each of spaces of FPC internal lines 168 (i.e., indicated S3) arranged at the second end portion 164 of the FPC 160. Thus, resistances of the first and second interconnection lines 152 and 154 may decrease.

In an example embodiment, The PCB 180 may include, for example, a flexible printed circuit board (FPCB). When the FPCB is applied in the display device 100, the FPCB may include the PCB 180 and the FPC 160, so that the FPCB may be attached on the edge of the display panel using the FOG method.

As described above, the display device 100 according to example embodiments may include the FPC 160 having the first end portion 162 and the second end portion 164, and with the width LS of the first end portion 162 being greater than the width SS of the second end portion 164, so that one FPC 160 may be connected to the plurality of driver integrated circuits 140. Thus, the lengths of the first and second interconnection lines 152 and 154 may decrease significantly compared with conventional interconnection lines. Also, each of spaces S1 and S2 between the first and second interconnection lines 152 and 154, respectively, may be greater than the conventional interconnection lines. As a result, the resistance of the first and second interconnection lines 152 and 154 may decrease, so that a defect on the display (e.g., horizontal lines on display area) caused by unintended impulses and external noises may be minimized or prevented.

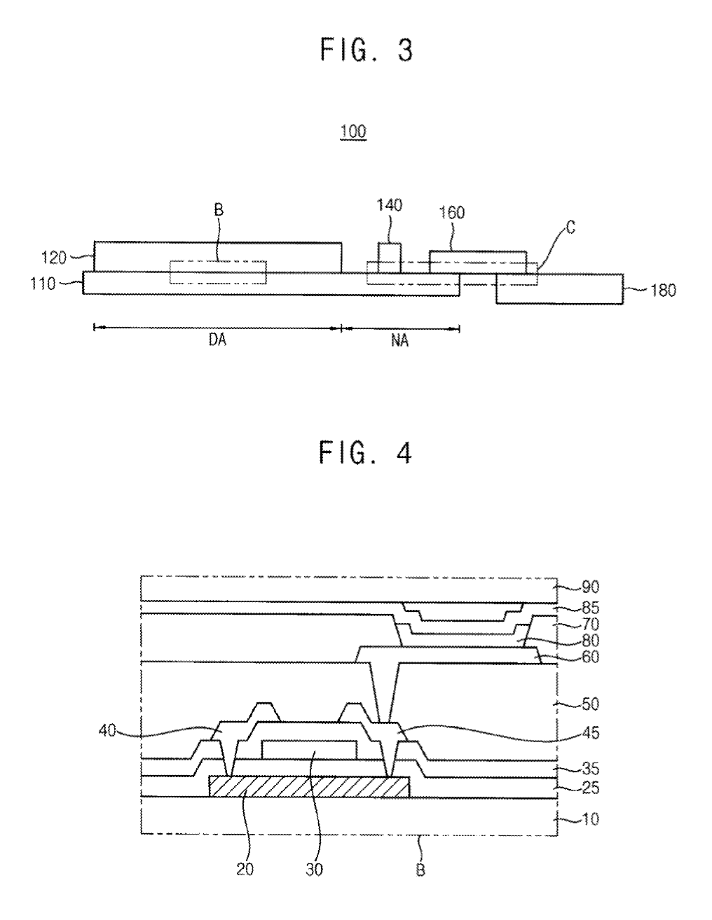

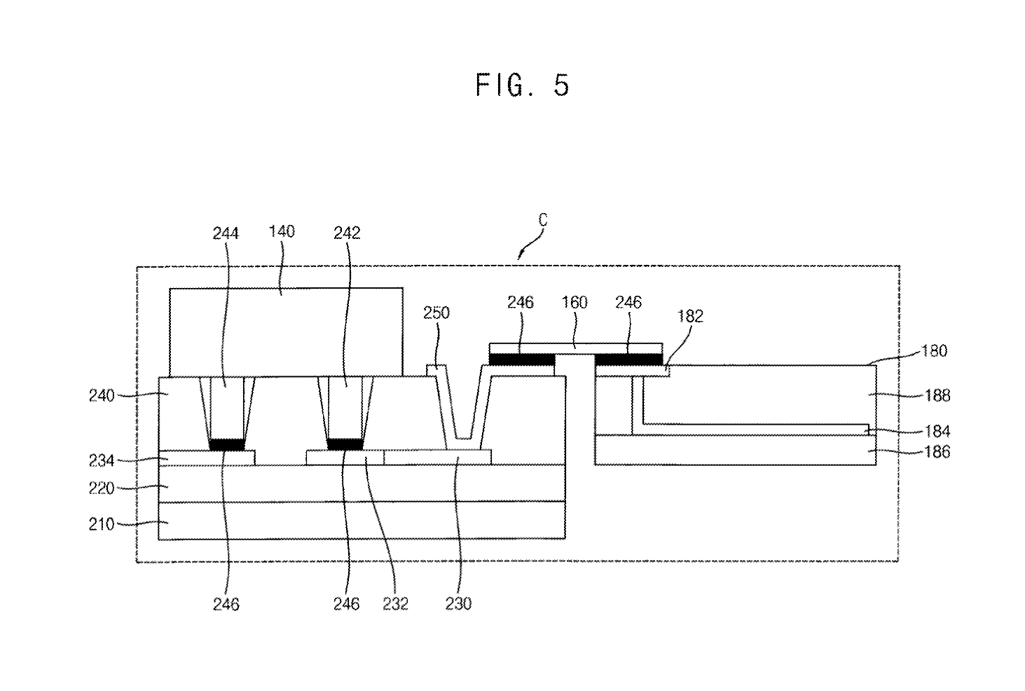

FIG. 3 is a cross-sectional view taken along the line I-I′ of FIG. 1, FIG. 4 is an enlarged view illustrating an example of a portion ‘B’ of FIG. 3, and FIG. 5 is an enlarged view illustrating an example of a portion ‘C’ of FIG. 3.

Referring to FIGS. 3 through 5, a display device 100 may include, for example, a display panel 110, a pixel unit 120, a driver integrated circuit 140, a FPC 160, and a PCB 180.

As illustrated in FIG. 3, the display panel 110 may have a display area DA and a non-display area NA. The pixel unit 120 may be arranged in the display area DA of the display panel 110. The driver integrated circuit 140, the FPC 160, and the PCB 180 may be arranged at the non-display area NA of the display panel 110.

As illustrated in FIGS. 3 and 4, the portion ‘B’ may be a portion of the pixel unit 120. A plurality of pixels in the pixel unit 120 may be coupled to the driver integrated circuit 140 formed at the non-display area NA through signal lines. The plurality of pixels may show an image when a driving signal is provided by the driver integrated circuit 140. In example embodiments, the pixel unit 120 may include, for example, a plurality of organic light emitting diodes but example embodiments are not limited thereto.

For example, the pixel unit 120 may include, for example, a base substrate 10, an active pattern 20, a metal pattern, a display element, and an encapsulating substrate 90. For example, in an exemplary embodiment, the base substrate 10 may include polyimide (PI), polyethersulfone (PES), polyethylenenaphthalate (PEN), polyethylene (PE), polyvinyl chloride (PVC), polyethylene terephthalate (PET), or combinations thereof. The metal pattern may include, for example, a gate electrode 30, a source electrode 40, and a drain electrode 45.

A gate insulation layer 25 and an inorganic insulation layer 35 may be disposed on the active pattern 20. An organic insulation layer 50 may be disposed on the metal pattern. The display element may be disposed on the organic insulation layer 50. The display element may include, for example, a first electrode 60, a light emitting structure 80, and a second electrode 85. Here, respective pixels may be defined (e.g., divided) by a pixel defining pattern 70. The pixel defining pattern 70 may be formed of, for example, one or more organic materials selected from benzocyclobutene, polyimide (PI), polyamide (PA), acrylic resin, and phenolic resin. Alternatively, in an example embodiment, the pixel defining pattern 70 may be formed of, for example, an inorganic material such as, for example, silicon nitride.

The active pattern 20 may include, for example, amorphous silicon, poly-silicon, semiconductor oxide, etc. A source region and a drain region may be formed at each of the end portions of the active pattern 20.

The gate insulation layer 25 may be disposed on the active pattern 20. The gate insulation layer 25 may entirely cover the active pattern 20. In an example embodiment, the gate insulation layer 25 may include, for example, silicon oxide, silicon nitride, silicon oxynitride (SiOxNy), aluminum oxide (AlOx), yttrium oxide (Y₂O₃), hafnium oxide (HfOx), zirconium oxide (ZrOx), aluminum nitride (AlN), aluminum oxynitride (AlNO), titanium oxide (TiOx), barium titanate (BaTiO3), lead titanate (PbTiO₃), etc.

The gate electrode 30 may be disposed on the gate insulation layer 25 and may overlap the active pattern 20. For example, the gate electrode 30 may overlap a center portion of the active pattern 20. In an example embodiment, the gate electrode 30 may include, for example, aluminum (Al), chromium (Cr), nickel (Ni), molybdenum (Mo), tungsten (W), magnesium (Mg), copper (Cu), titanium (Ti), tantalum (Ta), gold (Au), palladium (Pd), platinum (Pt), neodymium (Nd), zinc (Zn), cobalt (Co), silver (Ag), manganese (Mn) or their alloys, etc. Also, the gate electrode 30 may have a single layer or multi layer structure.

The inorganic insulation layer 35 may be disposed on the gate electrode 30 and may entirely cover the gate electrode 30. In an example embodiment, the inorganic layer 35 may include, for example, silicon oxide, silicon nitride, silicon oxynitride, etc.

The source electrode 40 may be electrically connected to the active pattern 20 through a first contact hole that is formed in the gate insulation layer 25 and the inorganic insulation layer 35. For example, the source electrode 40 may contact the source region of the active pattern 20. The drain electrode 45 may be electrically connected to the active pattern 20 through a second contact hole that is formed in the gate insulation layer 25 and the inorganic insulation layer 35. For example, the drain electrode 45 may contact the drain region of the active pattern 20. The source electrode 40 and the drain electrode 45 may each include, for example, aluminum (Al), chromium (Cr), nickel (Ni), molybdenum (Mo), tungsten (W), magnesium (Mg), copper (Cu), titanium (Ti), tantalum (Ta), gold (Au), palladium (Pd), platinum (Pt), neodymium (Nd), zinc (Zn), cobalt (Co), silver (Ag), manganese (Mn) or their alloys, etc.

The organic insulation layer 50 may be disposed on the inorganic insulation layer 35 on which the source electrode 40 and the drain electrode 45 are formed. For example, the organic insulation layer 50 may have a substantially flat surface.

The first electrode 60 may be disposed on the organic insulation layer 50. The first electrode 60 may be electrically connected to the drain electrode 45. The first electrode 60 may be formed by, for example, a transparent electrode. For example, the first electrode 60 may include indium zinc oxide (IZO), indium tin oxide (ITO), zinc oxide (ZnOx), tin oxide (SnOx), cadmium tin oxide (CTO), aluminum zinc oxide (AZO), indium tin zinc oxide (ITZO), cadmium oxide (CdO), hafnium oxide (HfO), indium gallium zinc oxide (InGaZnO), indium gallium zinc magnesium oxide (InGaZnMgO), indium gallium magnesium oxide (InGaMgO), indium gallium aluminum oxide (InGaAlO), etc. In an example embodiment, the first electrode 60 may be used as an anode that provides positive holes.

The pixel defining pattern 70 may be disposed on the organic insulation layer 50 on which the first electrode 60 is formed. The pixel defining pattern 70 may partially overlap two end portions of the first electrode 60.

The light emitting structure 80 may be disposed on the first electrode 60. The light emitting structure 80 may sequentially include, for example, a hole injection layer (HIL), a hole transfer layer (HTL), an emission layer (EML), an electron transfer layer (ETL) and an electron injection layer (EIL). In an example embodiment, the light emitting structure 80 may include, for example, light emitting materials that generate red light, green light, blue light, etc. Alternatively, the light emitting structure 80 may include, for example, a plurality of light emitting materials, each having a different wavelength or a mixture of these light emitting materials.

The second electrode 85 may be disposed on the light emitting structure 80. The second electrode 85 may overlap with the pixel defining pattern 70. The second electrode 85 may include, for example, substantially the same material as that of the first electrode 60. For example, the second electrode 85 may include indium zinc oxide (IZO), indium tin oxide (ITO), zinc oxide (ZnOx), tin oxide (SnOx), cadmium tin oxide (CTO), aluminum zinc oxide (AZO), indium tin zinc oxide (ITZO), cadmium oxide (CdO), hafnium oxide (HfO), indium gallium zinc oxide (InGaZnO), indium gallium zinc magnesium oxide (InGaZnMgO), indium gallium magnesium oxide (InGaMgO), indium gallium aluminum oxide (InGaAlO), etc. In an example embodiment, the second electrode 85 may be used, for example, as a cathode that provides electrons.

The encapsulating substrate 90 may face the base substrate 10 to encapsulate the display element. The encapsulating substrate 90 may include, for example, an insulation material. The encapsulating substrate 90 may have, for example, substantially the same material as that of the base substrate 10. For example, the encapsulating substrate 90 may include polyimide (PI).

Although it is illustrated in FIG. 4 that a thin film transistor included in the display device 100 has a top-gate structure, the structure of the thin film transistor included in the display device 100 according to example embodiments is not limited thereto. For example, the thin film transistor may alternatively have a bottom-gate structure.

As illustrated in FIGS. 3 and 5, the portion ‘C’ includes the driver integrated circuit 140, the FPC 160, an interconnection line 230, and the PCB 180. The driver integrated circuit 140, the FPC 160, the interconnection line 230, and the PCB 180 may be arranged at the non-display area NA of the display panel 110.

The PCB 180 may include, for example, a PCB bonding pad 182, a PCB line pattern 184, an insulation layer 186, a cover layer 188, a timing controller, a power supply, etc.

The PCB bonding pad 182 may be electrically and physically connected to a second end portion of the FPC 160 through an AFC 246. The ACF 246 may include, for example, a conductive particle for electrical connection and an adhesive resin for physical connection. In an example embodiment, the PCB line pattern 184 may transfer a data signal and a power supply voltage to the FPC 160. The data signal may be generated by the timing controller. The power supply voltage may be generated in the power supply. In an example embodiment, the PCB line pattern 184 may be formed with, for example, copper, aluminum, their alloys, etc. The insulation layer 186 and the cover layer 188 may be formed with an organic insulation material or an inorganic insulation material. The insulation layer 186 and the cover layer 188 may protect the PCB line pattern 184 and internal circuits such as, for example, the timing controller, the power supply, etc. from shocks, chemical damages, etc.

In an example embodiment, a first end portion of the FPC 160 may be electrically and physically connected to a FPC bonding pad 250 of the display panel 110 through the AFC 246. Thus, signals generated in the PCB may be transferred to the display panel 110 through the ACF 246. A width of the first end portion of the FPC 160 may be greater than a width of the second end portion of the FPC 160. The FPC 160 may be connected to a plurality of driver integrated circuits through a plurality of interconnection lines.

In an example embodiment, the driver integrated circuit 140 may include, for example, an input bump 242 and an output bump 244. The driver integrated circuit 140 may be connected to bonding pads 232 and 234 formed on a base substrate 210 through the ACF 246. The ACF 246 may include, for example, a conductive particle for electrical connection and an adhesive resin for physical connection.

In an example embodiment, the non-display area NA of the display panel 110 may include, for example, the base substrate 210, a first insulation layer 220 disposed on the base substrate 210, a first and a second driver integrated circuit bonding pads 232 and 234 disposed on the first insulation layer 220, the interconnection line 230 disposed on the first insulation layer 220, a second insulation layer 240 including a contact hole disposed on the first insulation layer 220, and a FPC bonding pad 250 disposed on the first insulation layer 220. The FPC bonding pad 250 may be formed along an inside wall of the contact hole. The FPC bonding pad 250 may be connected to the interconnection line 230.

The first insulation layer 220 and the gate insulation layer 25 (or the inorganic insulation layer 35) of the display area DA may be, for example, concurrently or simultaneously formed. The first insulation layer 220 may be, for example, substantially the same as or similar to the gate insulation layer 25 or the inorganic insulation layer 35. The second insulation layer 240 and the organic insulation layer 50 of the display area DA may be, for example, concurrently or simultaneously formed. The second insulation layer 240 may be, for example, substantially the same as or similar to the organic insulation layer 50.

In an example embodiment, FPC bonding pad 250 may be electrically and physically connected to the FPC 160. The FPC bonding pad 250 may be connected to the interconnection line 230 where the first driver integrated circuit bonding pad 232 is connected. Thus, the signal generated in the PCB 180 may be transferred to the driver integrated circuit 140 through the input bump 242.

The driving signal generated in the driver integrated circuit 140 may be transferred to the pixel unit 120 through the output bump 244. The output bump 244 may be electrically connected to the second driver integrated circuit bonding pad 234, so that the driving signal may be transferred to the pixel unit 120 through the second driver integrated circuit bonding pad 234.

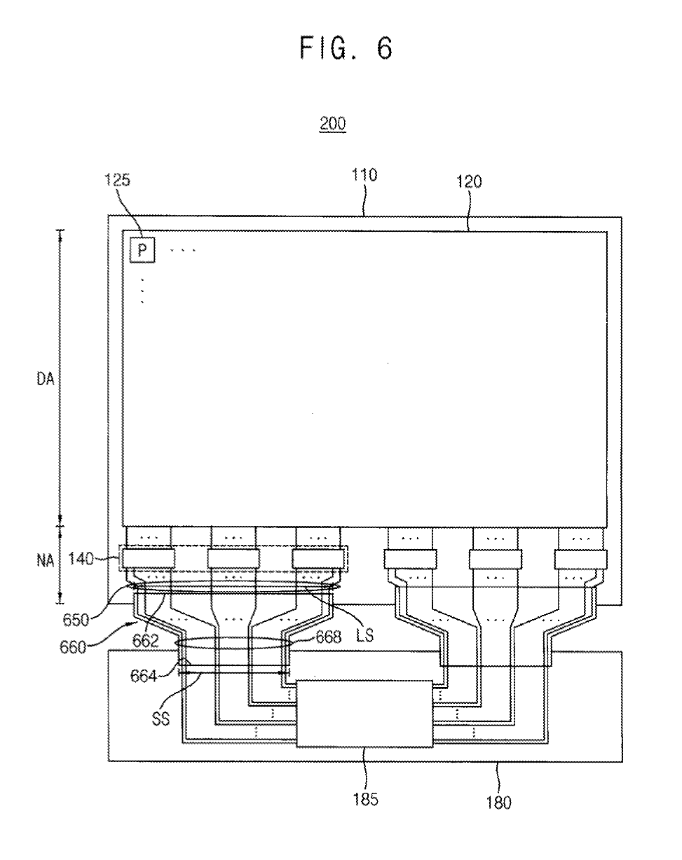

FIG. 6 is a plane view of a display device according to an example embodiment.

Referring to FIG. 6, a display device 200 may include, for example, a display panel 110, a plurality of driver integrated circuits 140, a FPC 660, and a plurality of interconnection lines 650.

According to example embodiments, the display device 100 may be any display device, such as, for example, a LCD device, an OLED device, a PDP, etc.

The display panel 110 may include a display area DA where a pixel unit 120 is formed and a non-display area NA on which a plurality of driver integrated circuits 140 and a portion of FPC 660 are mounted. The pixel unit 120 may be formed in, for example, a matrix form having a plurality of rows and a plurality of columns.

The plurality of driver integrated circuits 140 may be mounted on the non-display area NA of the display panel 110 for high resolution of the display device 100 using, for example, a COG method. The driver integrated circuits 140 may generate driving signals. Although FIG. 6 illustrates an example of the display device 100 where six driver integrated circuits 140 are mounted on the display panel 110, the number of driver integrated circuits is not limited thereto.

The PCB 180 may be configured to provide a signal to the driver integrated circuits 140. In an example embodiment, the signal may include, for example, the power supply voltage, and the data signal. The data signal may be provided to the driver integrated circuits 140 to control the operation of the display device. In an example embodiment, the PCB 180 may include, for example, a timing controller 185 generating the signals and a power supply generating the power supply voltages.

A first end portion 662 of the FPC 660 may be attached on an edge of the non-display area NA of the display panel 110 using, for example, a FOG method. A second end portion 664 of the FPC 660 may be attached on the PCB 180. In an example embodiment, the display panel 110 may be electrically connected to the FPC 660 through the ACF, and the PCB 180 may be electrically connected to the FPC 660 through the ACF. Thus, the FPC 660 may be configured to transfer the signal from the PCB 180 to the display panel 110, and the driver integrated circuits 140. The ACF may include, for example, a conductive particle for electrical connection and an adhesive resin for physical connection.

In an example embodiment, the first end portion 662 of the FPC 660 may have a first width LS and the second end portion 664 of FPC 660 may have a second width SS. The first width LS may be greater than the second width SS. For example, as illustrated in FIG. 6, the first width LS may correspond to a distance where three driver integrated circuits are arranged. Thus, one FPC 660 may be connected to the interconnection lines that three driver integrated circuits are connected. In this, the second width SS of the second end portion 664 connected to the PCB 180 does not increase, so that a width of a PCB bonding pad unit may not be increased compared with a conventional PCB bonding pad unit.

In an example embodiment, lengths of the interconnection lines 650 may correspond to the shortest distance between the driver integrated circuits 140 and the FPC 660, respectively. Alternatively, in an example embodiment, lengths of all of the interconnection lines 650 may be substantially the same. Moreover, in an example embodiment, each of spaces between the interconnection lines 650 may be greater than each of spaces of FPC internal lines 668 that are arranged at the second end portion 664 of the FPC 660. Thus, the resistances of the interconnection lines 650 may decrease compared with conventional interconnection lines.

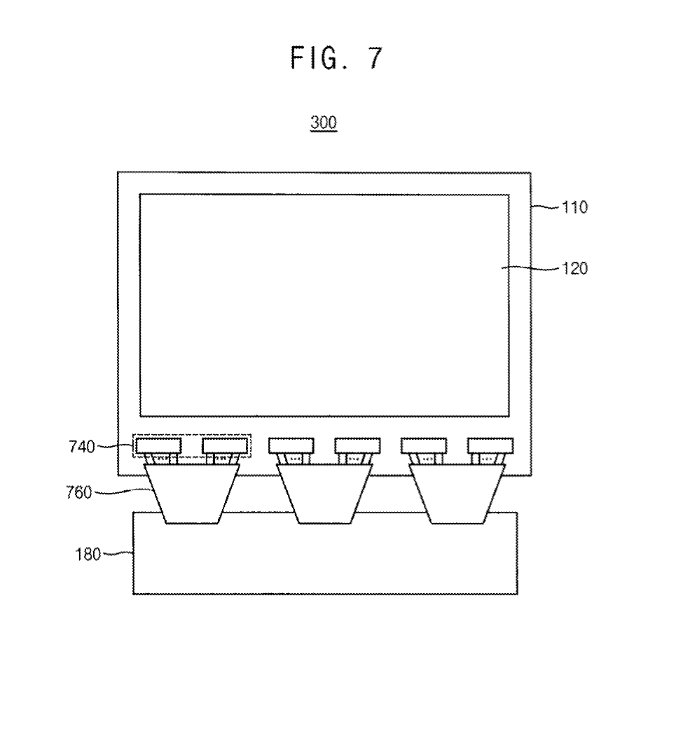

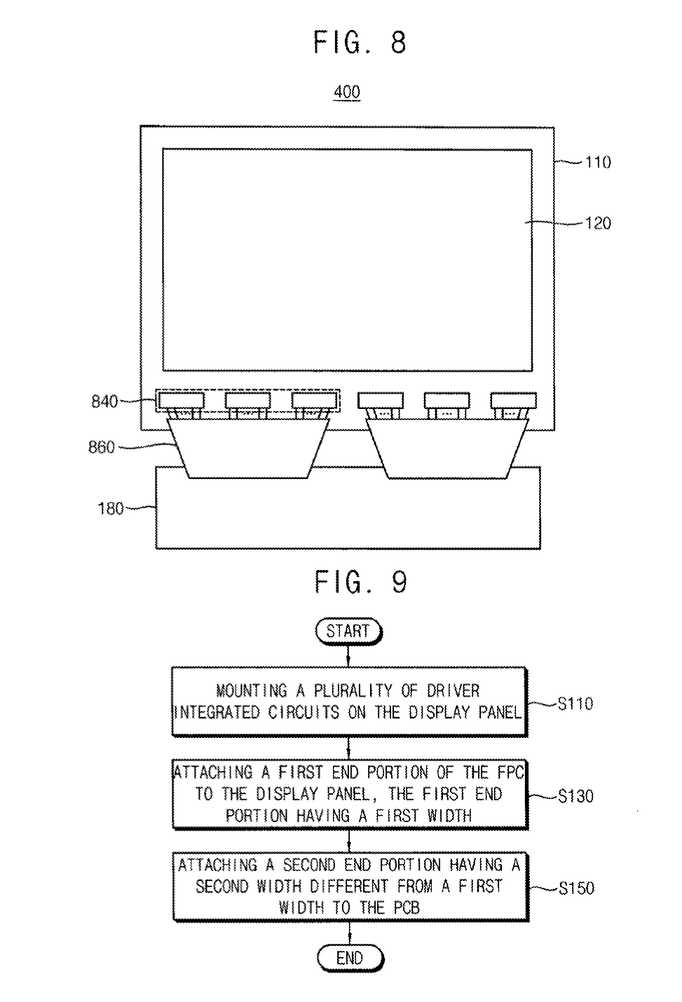

FIG. 7 is a plane view of a display device according to an example embodiment, and FIG. 8 is a plane view of a display device according to an example embodiment. In FIGS. 7 and 8, like reference numerals are used to designate elements of the display device the same as those in FIG. 1, and detailed description of these elements may be omitted.

Referring to FIG. 7, a display device 300 may include a display panel 110, a pixel unit 120, a plurality of driver integrated circuits 740, an FPC 760, a PCB 180, and a plurality of interconnection lines. In addition, referring to FIG. 8, a display device 400 may include a display panel 110, a pixel unit 120, a plurality of driver integrated circuits 840, an FPC 860, a PCB 180 and a plurality of interconnection lines.

As illustrated in FIG. 7, FPC 760 may have, for example, a trapezoid shape where a width of a first end portion is greater than a width of a second end portion opposite to the first end portion. The FPC 760 may be electrically connected to the two driver integrated circuits 740 through interconnection lines. When six driver integrated circuits are mounted on the display panel 110, three FPCs may be attached on the display panel 110 by a FOG method.

In an example embodiment, lengths of interconnection lines may correspond to the shortest distance between the driver integrated circuits 740 and the FPC 760, respectively. Alternatively, in an example embodiment, the lengths of all of the interconnection lines may be substantially the same. Moreover, in an example embodiment, each of spaces between the interconnection lines may be greater than each of spaces of FPC internal lines.

The second end portion of the FPC 760 may be attached to the PCB 180, so that the FPC 760 may transfer signals generated in the PCB 180 to the display panel 110.

As illustrated in FIG. 8, the FPC 860 may have, for example, the trapezoid shape where a width of a first end portion of the FPC 860 is greater than a width of a second end portion of the FPC 860 opposite to the first end portion. The FPC 860 may be electrically connected to the three driver integrated circuits 840 through interconnection lines. When six driver integrated circuits 840 are mounted on the display panel 110, two FPCs may be attached on the display panel 110 by the FOG method. As these are examples, the number of driver integrated circuits 840 connected to one FPC is not limited thereto.

FIG. 9 is a flow chart of a method of manufacturing a display device according to an example embodiment.

Referring to FIG. 9, the method of manufacturing the display device according to an example embodiment may include, for example, mounting a plurality of driver integrated circuits on a non-display area of a display panel by a COG method (S110), attaching a first end portion of a FPC on the display panel by a FOG method (S130), in which the first end portion has a first width, and attaching a second end portion of the FPC opposite to the first end portion on a PCB (S150). The second end portion may have a second width that is different from the first width.

The plurality of driver integrated circuits may be mounted on the non-display area of the display panel (S110). For example, the driver integrated circuits may be mounted on a glass substrate of the display panel by disposing an ACF between the driver integrated circuits and the glass substrate and by pressing at high temperature. According to example embodiments, the driver integrated circuits may be, for example, a data driver integrated circuit applying a data voltage to the display area of the display panel, a scan driver integrated circuit applying a gate voltage to the display area of the display panel, or an integrated driver integrated circuit where the data driver and the scan driver are integrated. The plurality of driver integrated circuits may be mounted on the non-display area of the display panel for high resolution of the display device. The driver integrated circuits may include, for example, an input bump unit and an output bump unit. The input bump unit and the output bump unit may be formed with, for example, a conductive material. The input bump unit and the output bump unit may be connected to a driver integrated circuit bonding pad unit of the display panel. Thus, the driver integrated circuits may be configured to receive the signal through the input bump and to transfer a driving signal (e.g., a data signal, a gate signal, etc) to the display area (i.e., a pixel unit) through the out bump unit.

The first end portion of the FPC may be attached on the display panel (S130). The FPC may be configured to transfer signals generated in the PCB to the display panel and/or the driver integrated circuits. In an example embodiment, the first width (i.e., the width of the first end portion) may be greater than the second width (i.e., the width of the second end portion). Alternatively, in an example embodiment, the FPC may have, for example, a trapezoid shape where the first width is greater than the second width. Thus, one FPC may be electrically connected to the plurality of driver integrated circuits. In an example embodiment, the FPC may be connected to the display panel through, for example, the ACF. The ACF may include, for example, a conductive particle for electrical connection and an adhesive resin for physical connection. For example, a FPC bonding pad unit may be formed on the display panel. The ACF may be attached on the FPC bonding pad unit. The FPC may be mounted on the display panel by, for example, disposing an ACF between the FPC and the FPC bonding pad unit and by pressing at high temperature.

In an example embodiment, interconnection lines may be formed in the non-display area of the display panel to connect the FPC to the driver integrated circuits. The interconnection lines may be contacted to the driver integrated circuits and the FPC bonding pad unit. The interconnection lines may be formed with, for example, a transparent conductive material or a low-resistance metal (e.g., copper, aluminum, etc). The interconnection lines may be formed by, for example, a mask patterning process, etc.

In an example embodiment, the FPC may be connected to a first driver integrated circuit through first interconnection lines and may be connected to a second driver integrated circuit through second interconnection lines. A length of each of the first interconnection lines may be, for example, substantially the same as a length of each of the second interconnection lines. In other words, the lengths of the first and second interconnection lines may correspond to the shortest distance between the first and second driver integrated circuits and the FPC, respectively.

In an example embodiment, each of spaces between the first interconnection lines and each of spaces between the second interconnection lines may be greater than each of spaces of FPC internal lines arranged at the second end portion of the FPC. Thus, the resistances of the interconnection lines may decrease.

The second end portion of the FPC having the second width different from the first width may be attached on the PCB (S150). The PCB may be configured to provide the signal to the driver integrated circuits. In an example embodiment, the signal may include, for example, a data signal controlling operation of the display device and a power supply voltage. The PCB may include, for example, a PCB bonding pad unit attached to the FPC. The PCB bonding pad unit may be formed with, for example, a conductive material. In an example embodiment, the FPC may be electrically connected to the PCB through the ACF. In other words, the FPC may be attached on the PCB by the FOG method. For example, the FPC may be mounted on the display panel by disposing an ACF between the FPC and the FPC bonding pad unit and by pressing at high temperature. A size of PCB bonding pad unit may correspond to the second width of the FPC (i.e. the width of the second end portion of the FPC). Also, when a plurality of FPCs are mounted on the display device, the number of PCB bonding pad unit may be the same as the number of the plurality of FPCs.

As described above, the method of manufacturing the display device according to example embodiments may include attaching the FPC having the first end portion and the second end portion to the display panel and the PCB, and in which the width of the first end portion being greater than the width of the second end portion. Thus, one FPC may be electrically connected to the plurality of driver integrated circuits and lengths of the interconnection lines connecting the FPC to the driver integrated circuits may be decreased significantly compared with conventional interconnection lines. Also, each of spaces between the interconnection lines may be greater than the conventional interconnection lines. Thus, the resistance of the interconnection lines may decrease, so that a defect on the display (e.g., horizontal lines on display area) caused by unintended impulses and external noises may be minimized or prevented. Also, the interconnection lines may be relatively simply arranged, so that reliability of the display device may be increased.

Example embodiments may be applied to any display device and any system including the display device. For example, example embodiments may be applied to a display device, such as, for example, a LCD device, an OLED device, a PDP display device, etc.

Having described example embodiments of the inventive concept, it is further noted that it is readily apparent to those of ordinary skill in the art that various modifications may be made without departing from the spirit and scope of the invention which is defined by the metes and bounds of the appended claims.

What is claimed is:

1. A display device, comprising:
a display panel including a display area and a non-display area;
a plurality of driver integrated circuits mounted on the non-display area of the display panel by a chip-on-glass (COG) method;
a printed circuit board (PCB) configured to provide a signal to the plurality of driver integrated circuits; and
a flexible printed circuit (FPC) configured to transfer the signal from the PCB to the plurality of driver integrated circuits, the FPC having a first end portion and a second end portion opposite to the first end portion, the first end portion attached on the non-display area of the display panel by a film-on-glass (FOG) method, the second end portion attached on the PCB, and wherein a width of the second end portion being different from a width of the first end portion.

2. The display device of claim 1, wherein the width of the first end portion is greater than the width of the second end portion.

3. The display device of claim 1, wherein the FPC has a trapezoid shape and wherein the width of the first end portion is greater than the width of the second end portion.

4. The display device of claim 1, further comprising:
a plurality of interconnection lines disposed on the non-display area of the display panel, the plurality of interconnection lines electrically connecting the plurality of driver integrated circuits to the FPC.

5. The display device of claim 4, wherein the plurality of driver integrated circuits include a first driver integrated circuit and a second driver integrated circuit that is adjacent to the first driver integrated circuit,
wherein the plurality of interconnection lines include a plurality of first interconnection lines connecting the first driver integrated circuit to the FPC and a plurality of second interconnection lines connecting the second driver integrated circuit to the FPC, and
wherein a length of each of the first interconnection lines is substantially the same as a length of each of the second interconnection lines.

6. The display device of claim 5, wherein each of spaces between the first interconnection lines is greater than each of spaces of FPC internal lines that are disposed at the second end portion of the FPC.

7. The display device of claim 4, wherein the interconnection lines include a transparent conductive material.

8. The display device of claim 4, wherein the interconnection lines include copper or aluminum.

9. The display device of claim 1, wherein the PCB is a flexible printed circuit board (FPCB).

10. The display device of claim 1, wherein the signal provided to the driver integrated circuits includes a data signal and a power supply voltage.

11. The display device of claim 1, wherein the FPC is electrically connected to the display panel through an anisotropic conductive film (ACF).

12. The display device of claim 1, wherein the FPC is electrically connected to the PCB through an anisotropic conductive film (ACF).

13. A method of manufacturing a display device, the method comprising:
mounting a plurality of driver integrated circuits on a non-display area of a display panel by a chip-on-glass (COG) method;
attaching a first end portion of a flexible printed circuit (FPC) on the display panel by a film-on-glass (FOG) method, the first end portion having a first width;
attaching a second end portion of the FPC opposite to the first end portion on a printed circuit board (PCB) that is configured to provide a signal to the plurality of driver integrated circuits, the second end portion having a second width that is different from the first width.

14. The method of claim 13, wherein the first width is greater than the second width.

15. The method of claim 13, further comprising:
forming a plurality of interconnection lines on the non-display area of the display panel, the plurality of interconnection lines electrically connecting the plurality of driver integrated circuits to the FPC.

16. The method of claim 15, wherein the plurality of driver integrated circuits include a first driver integrated circuit and a second driver integrated circuit that is adjacent to the first driver integrated circuit,
wherein the plurality of interconnection lines include a plurality of first interconnection lines connecting the first driver integrated circuit chip to the FPC and a plurality of second interconnection lines connecting the second driver integrated circuit to the FPC, and
wherein a length of each of the first interconnection lines is substantially the same as a length of each of the second interconnection lines.

17. The method of claim 16, wherein each of spaces between the first interconnection lines is greater than each of spaces of FPC internal lines that are disposed at the second end portion of the FPC.

18. The method of clam 13, wherein the FPC is electrically connected to the display panel through an anisotropic conductive film (ACF).

19. The method of claim 13, wherein the FPC is electrically connected to the PCB through an anisotropic conductive film (ACF).

20. A display device, comprising:
a display panel including a display area and a non-display area; and
a pixel unit disposed in the display area of the display panel,
wherein the non-display area of the display panel comprises:
a non-display area base substrate,
a first insulation layer disposed on the non-display area base substrate;
a first driver integrated circuit bonding pad and a second driver integrated circuit bonding pad disposed on the first insulation layer,
an interconnection line disposed on the first insulation layer,
a second insulation layer including a contact hole disposed on the first insulation layer,
a flexible printed circuit (FPC) bonding pad disposed on the first insulation layer and connected to the interconnection line,
a driver integrated circuit disposed on the second insulation layer and including an input bump and an output bump which are respectively connected to the first driver integrated circuit bonding pad and the second driver integrated circuit bonding pad, respectively via an anisotropic conductive film (ACF), and wherein the driver integrated circuit is coupled to the pixel unit,
a flexible printed circuit (FPC) configured to transfer the signal from the PCB to the driver integrated circuit, the FPC having a first end portion and a second end portion opposite to the first end portion, the first end portion electrically and physically connected to the FPC bonding pad via an anisotropic conductive film (AFC), wherein a width of the first end portion is greater than a width of the second end portion, and
a printed circuit board (PCB) configured to provide a signal to the driver integrated circuit, wherein the PCB includes a PCB bonding pad which is electrically and physically connected to the second end portion of the FPC via an anisotropic conductive film (AFC), a PCB line pattern configured to transfer a data signal and a power supply voltage to the FPC, and a cover layer configured to protect the PCB line pattern from damage.
